(19) United States
(12) Patent Application Publication
(10) Pub. No.: US 2008/0003790 A1
(43) Pub. Date: Jan. 3, 2008

(54) METHOD FOR FORMING A GATE OF A SEMICONDUCTOR DEVICE

(75) Inventors: Hye Jin Seo, Suwon-si (KR); Jae Soo Kim, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/618,047

(22) Filed: Dec. 29, 2006

(30) Foreign Application Priority Data
Jun. 30, 2006 (JP) 10-2006-0061512

(51) Int. Cl. H01L 21/3205; H01L 21/4763

(52) U.S. Cl. 438/585; 438/592; 438/595

(57) ABSTRACT

A method for forming a gate of a semiconductor device includes providing a polysilicon layer over a semiconductor substrate, the polysilicon having dopants. A conductive layer is formed over the polysilicon layer. The conductive layer and the polysilicon layer are etched to form a gate structure, the gate structure having a sidewall that is damaged by the etching. The sidewall of the gate structure is nitridated to compensate for the damage to the sidewall of the gate structure.

### CROSS-REFERENCE TO RELATED APPLICATION

The present application claims priority to Korean application number 10-2006-0061512, filed on Jun. 30, 2006, which is incorporated by reference in its entirety.

### BACKGROUND OF THE INVENTION

The present invention relates to a method for fabricating a semiconductor device, and more particularly to a method for forming a gate of a semiconductor device. Polysilicon is commonly used for forming a gate of a semiconductor device. This is because polysilicon has a high melting point, ease in forming a thin layer and line pattern, ability to form a flat surface, and the like. Conventionally, in order to simplify a manufacturing process, n-type doped polysilicon is used for forming gates of both NMOS (N-Channel Metal Oxide Semiconductor) transistors and PMOS (P-Channel Metal Oxide Semiconductor) transistors. This requires the formation of a buried channel in the PMOS transistor. As the design rule of a DRAM continues to gradually decrease and as the demands for high power and high-speed operation have recently increased, the PMOS with the buried channel cannot satisfy these requirements.

To solve this problem, a dual-gate process is widely used. The dual-gate process means that the gate in the NMOS is formed by the N-type doped polysilicon and the gate in the PMOS is formed by the P-type doped polysilicon.

### SUMMARY OF THE INVENTION

Embodiments of the invention are directed to a method for forming a gate of a semiconductor device. The device has a dual-gate structure in certain embodiments of the present invention.

In one embodiment, a method for forming a gate of a semiconductor device comprising the steps of: forming a polysilicon layer on a gate insulating layer formed on a semiconductor substrate; doping the polysilicon layer by implanting conductive dopant ions in the polysilicon layer; forming a metal electrode layer on the polysilicon layer; forming a hard mask layer on the metal electrode layer; forming a gate pattern by patterning the metal electrode layer and the poly-silicon layer by using the hard mask layer as an etching mask; and nitridating a side surface of the gate pattern.

The step of forming a polysilicon layer on a gate insulating layer includes the step of: depositing an un-doped amorphous silicon layer or a doped poly-silicon layer on the gate insulating layer.

In one embodiment, a method for forming a gate of a semiconductor device includes providing a polysilicon layer over a semiconductor substrate, the polysilicon having dopants. A conductive layer is formed over the polysilicon layer. The conductive layer and the polysilicon layer are etched to form a gate structure, the gate structure having a sidewall that is damaged by the etching. The sidewall of the gate structure is nitridated to compensate for the damage to the sidewall of the gate structure. The nitridating step is performed using plasma. The plasma includes nitrogen. The nitridating results in forming a thin nitride film on the sidewall of the gate structure. The nitride layer 228 has a thickness of about 20 Å to 60 Å.

### BRIEF DESCRIPTION OF THE DRAWINGS

FIG. 1 is a cross-sectional view showing the movement of boron (B) ion in a poly-silicon layer during a heat-treatment process.

FIG. 2 is a cross-sectional view showing a method for forming a gate pattern on a semiconductor substrate in accordance with the present invention.

FIG. 3 is a cross-sectional view showing a state of forming a nitride layer on a side surface of a gate pattern in accordance with the present invention.

### DESCRIPTION OF SPECIFIC EMBODIMENTS

The present invention relates to a method for forming a gate of a semiconductor device. The device has a dual-gate structure in certain embodiments of the present invention. A poly-silicon layer is formed on a gate insulating layer formed on a semiconductor substrate. The poly-silicon layer is doped by implanting a conductive dopant ion. A metal electrode layer is formed on the poly-silicon layer. A hard mask layer is formed on the metal electrode layer. A gate pattern is formed by patterning the metal electrode layer and the poly-silicon layer by using the hard mask layer as an etching mask. A side surface of the gate pattern is nitrided.

According to an embodiment of the present invention, the damage generated during the gate patterning can be compensated, and the out-diffusion (or segregation) of the dopant implanted in the polysilicon layer can be prevented during the heat treatment process. Also, since the nitridation process can be performed at relatively low temperature, the lifting phenomenon of the gate pattern can be prohibited by preventing the heat generated stress between the metal electrode layer and the hard mask layer.

When etching the metal electrode layer and the polysilicon layer to form the gate electrode, side walls of the polysilicon layer and the metal electrode layer are damaged. To compensate the damage, a heat-treatment process is performed. However, during the heat-treatment process, out-diffusion or segregation of the boron (B) ions, which is implanted in the PMOS area, occurs.

FIG. 1 is a cross-sectional view showing movement of the boron (B) ions in the polysilicon layer during the heat-treatment process for compensating the damage of the gate pattern.

A reference numeral [symbol] illustrates the segregation of the boron (B) ions from the polysilicon layer 122 toward the metal electrode layer 124, [symbol] illustrates the segregation of the boron (B) ions between the metal electrode layer 124 and the hard mask layer 126, [symbol] illustrates the out-diffusion of the boron (B) ions through the surface of the metal electrode layer 126 or the segregation of the boron (B) ions toward the thin oxide layer 128, [symbol] illustrates the out-diffusion of the boron (B) ions through the surface of the polysilicon layer 122 or the segregation of the boron (B) ions toward the thin oxide layer 128, and [symbol] illustrates the penetration of the boron (B) ions toward the semiconductor substrate 100 through the gate insulating layer 112.

Such out-diffusion or segregation of the boron (B) ions causes a problem that the amount of the boron (B) doped in the polysilicon layer is decreased from the doping amount which is initially set, and so the properties of the semiconductor device cannot be estimated. Further, if the boron (B) ions are diffused to the gate insulating layer through the side wall of the gate pattern, the properties of the gate insulating layer are deteriorated, and the reliability of the device suffers severe damage.

Because the heat-treatment process is performed at the temperature of 850° C. or more, a lifting phenomenon of the gate pattern occurs by stress of the nitride layer which is used as the metal electrode layer and the hard mask layer.

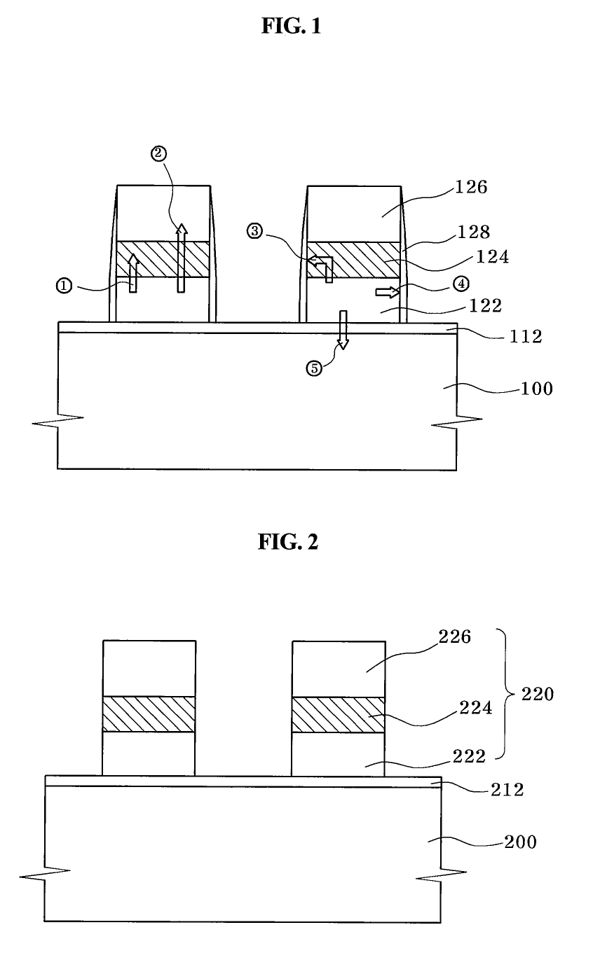

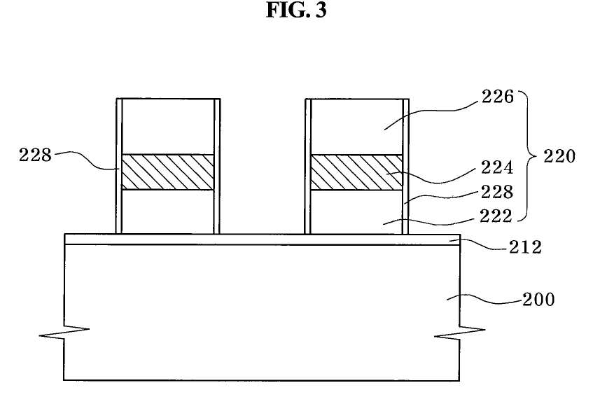

FIG. 2 is a cross-sectional view showing a method for forming a gate pattern on a semiconductor substrate in accordance with one embodiment of the present invention. An isolation layer (not shown) for defining an active area and a non-active area is formed on a semiconductor substrate 200 according to a common method. Ion implantation and heat treatment processes are performed to form a well in the semiconductor substrate 200. A gate insulating layer 212 is formed by growing an oxide layer on the semiconductor substrate 200. The gate insulating layer 212 is formed by a wet or dry oxidation method at a temperature of about 750° C. to 900° C., and has a thickness of about 30 Å to 60 Å. A polysilicon layer 222 is deposited on the gate insulating layer 212 by using a Low Pressure Chemical Vapor Deposition (LPCVD) method. The polysilicon layer 222 may be formed by depositing an un-doped amorphous silicon layer or depositing a doped polysilicon layer by using silane (SiH₄) and phosphine (PH₃) as a source gas.

A mask pattern (not shown) is formed on the polysilicon layer 222 to define an area in which a P-type gate electrode is formed. P-type dopants (e.g., boron (B) ions) are implanted into the polysilicon layer 222 in the PMOS area. The mask pattern for the P-type gate electrode is removed, and a mask pattern (not shown) is formed to define an area in which an N-type gate electrode is formed. N-type dopants (e.g., phosphorus (P) ions) are implanted in the poly-silicon layer 222 in the NMOS area. The mask pattern for the N-type gate electrode is removed, and the semiconductor substrate 200 is heat treated in order to activate the implanted dopant ions. The heat treatment process is performed at the temperature of about 950° C. by using a rapid thermal anneal (RTA) process.

A metal electrode layer 224 for forming the gate electrode is formed by depositing tungsten (W) or tungsten silicide (WSi) on the polysilicon layer 222. A nitride layer is deposited on the metal electrode layer 224, and a hard mask layer 226 for forming a gate pattern is formed by patterning the deposited nitride layer. The gate pattern 220 is formed by patterning the metal electrode layer 224, the polysilicon layer 222 and the gate insulating layer 212 in order by using the hard mask layer 226 as an etching mask.

FIG. 3 is a cross-sectional view showing a state of forming the nitride layer on the side surface of the gate pattern 220. A process of nitridating the gate pattern 220 is performed by using nitrogen plasma. Nitrogen gas N2 or ammonium gas NH3 is used as a source gas. In order to minimize the plasma depth, the nitridation process is performed by using a microwave at 2.45 GHz at a temperature of 500° C. or more and a pressure of 300 Torr or more. In the present embodiment, the nitridation process is performed at a temperature that is no more than f 550° C., or 600° C., or 650° C., or 700° C., or 750° C. By this process, the side surface of the gate pattern 220 is nitridated, and a thin nitride layer 228 is formed on the side surface of the gate pattern 220. The nitride layer 228 has a thickness of about 20 Å to 60 Å. The nitride layer 228 compensates damages to the sidewalls of the gate pattern by the etching process used to obtain the gate pattern. The nitride layer 228 prevents (or reduces) out-diffusion or segregation of the dopants implanted in the polysilicon layer 222 during the heat-treatment process. The nitridation process can be performed at the temperature of about 500° C. or no more than 600° C. according to one implementation. This is significantly lower temperature than the temperature of 850° C. used for the conventional heat-treatment process. Therefore, a lifting phenomenon of the gate pattern can be prevented by reducing the heat generated stress between the metal electrode layer 224 and the hard mask layer 226.

Although the embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for forming a gate of a semiconductor device, the method comprising:
providing a polysilicon layer over a semiconductor substrate, the polysilicon having dopants;
forming a conductive layer over the polysilicon layer;
etching the conductive layer and the polysilicon layer to form a gate structure, the gate structure having a sidewall that is damaged by the etching; and
nitridating the sidewall of the gate structure to compensate for the damage to the sidewall of the gate structure.

2. The method of claim 1, wherein the nitridating step is performed using plasma.

3. The method of claim 2, wherein the plasma includes nitrogen.

4. The method of claim 1, wherein the nitridating results in forming a thin nitride film on the sidewall of the gate structure.

5. The method of claim 4, wherein the thin nitride film has a thickness of about 20 Å to 60 Å.

6. The method of claim 5, wherein the nitridating is performed at a temperature of no more than 650° C.

7. The method of claim 5, wherein the nitridating is performed at a temperature of no more than 600° C.

8. The method of claim 4, wherein the nitridating is performed at a temperature of no more than 650° C.

9. The method of claim 1, wherein the conductive layer includes metal.

10. The method of claim 1, wherein the nitridating step forms a nitride film on the sidewall of the gate structure using plasma including nitrogen.

11. The method of claim 10, wherein the nitridating step uses a micro-wave of 2.45 GHz.

12. The method of claim 1, wherein the nitridating step is performed in a temperature between 500° C. to 700° C.

13. The method according to claim 1, wherein the conductive layer includes tungsten.

14. The method of claim 13, wherein the conductive layer is tungsten silicide.
